(19) United States
(12) Patent Application Publication
(10) Pub. No.: US 2020/0391259 A1
(43) Pub. Date: Dec. 17, 2020

(54) SUBSTRATE HOLDER AND SUBSTRATE SUPPORT DEVICE INCLUDING THE SUBSTRATE HOLDER

(71) Applicant: KCTECH CO., LTD., Gyeonggi-do (KR)

(72) Inventors: In Chul SHIN, Gyeonggi-do (KR); Hyun O KIM, Gyeonggi-do (KR)

(73) Assignee: KCTECH CO., LTD., Gyeonggi-do (KR)

(21) Appl. No.: 16/899,588

(22) Filed: Jun. 12, 2020

(30) Foreign Application Priority Data
Jun. 14, 2019 (KR) 10-2019-0070766

(51) Int. Cl. B08B 13/00; B08B 3/04; H01L 21/687; H01L 21/67

(52) U.S. Cl. CPC B08B 13/00; H01L 21/67051; H01L 21/68764; B08B 3/04

(57) ABSTRACT

A substrate holder and a substrate support device including the substrate holder are disclosed. The substrate holder includes a rotating portion configured to rotate on a rotation axis, a supporting portion connected to the rotating portion to surround an outer surface of the rotating portion in a circumferential direction of the rotating portion, and a first fastening portion formed on the outer surface of the rotating portion and a second fastening portion formed on a contact surface of the supporting portion that contacts the rotating portion and configured to be fastened to the first fastening portion.

### CROSS-REFERENCE TO RELATED APPLICATION(S)

This application claims the benefit under 35 USC §119(a) of Korean Patent Application No. 10-2019-0070766 filed on Jun. 14, 2019, in the Korean Intellectual Property Office, the entire disclosure of which is incorporated herein by reference for all purposes.

### BACKGROUND

### 1. Field

One or more example embodiments relate to a substrate holder and a substrate support device including the substrate holder.

### 2. Description of Related Art

A semiconductor device is manufactured through various processes including a deposition process, a photolithographic process, and an etching process to be performed on a substrate such as a wafer and the like. There is also a cleaning process to remove foreign substances such as unnecessary thin films and particles that may remain on a substrate. For example, there are numerous foreign substances left on a surface of a substrate obtained by performing a chemical-mechanical polishing process, and thus the cleaning process may be required to remove such foreign substances.

In the cleaning process for a substrate, a substrate support device may rotate a substrate while supporting an edge of the substrate. A cleaning fluid may be sprayed over a surface of the substrate that is rotating, and thus the sprayed cleaning fluid may be dispersed from the surface of the substrate by a centrifugal force due to the rotation of the substrate.

The substrate may be supported by a substrate holder. The substrate holder may rotate on a central axis, and include a plurality of materials to stably maintain a set position during the rotation and prevent the substrate from being damaged by an impact.

According to related arts, a substrate holder may include a plurality of portions of different materials that are connected to each other. For example, a portion to be connected to a rotation axis may be formed with a material having a high hardness, and a portion to be in contact with a substrate may be formed with a material having a relatively low hardness and high frictional force.

However, when connecting the portions of different materials, the portions connected to each other may be disconnected by an impact during the rotation, and thus a rotation speed of the substrate may become inconsistent and a substrate cleaning efficiency may be degraded.

The above description has been possessed or acquired by the inventor(s) in the course of conceiving the present disclosure and is not necessarily an art publicly known before the present application is filed.

### SUMMARY

An aspect provides a substrate holder and a substrate support device including the substrate holder that may effectively prevent a supporting portion and a rotating portion from being separated during a rotation by increasing a contact area between the supporting portion and the rotating portion.

Another aspect provides a substrate holder and a substrate support device including the substrate holder that may achieve a locking function both in a horizontal direction and in a vertical direction by a first fastening portion and a second fastening portion being fastened together.

According to an example embodiment, there is provided a substrate holder including a rotating portion configured to rotate on a rotation axis, a supporting portion connected to the rotating portion to surround an outer surface of the rotating portion in a circumferential direction of the rotating portion, and a first fastening portion formed on the outer surface of the rotating portion and a second fastening portion formed on a contact surface of the supporting portion that contacts the rotating portion and configured to be fastened to the first fastening portion.

The rotating portion may include a lower portion and an upper portion that are stepped with each other outwardly. The lower portion and the upper portion may have a stepped surface that is formed therebetween.

Based on a cross section parallel to the rotation axis, an outer surface of the lower portion and an outer surface of the upper portion may be parallel to the rotation axis, and the stepped surface may be perpendicular to the rotation axis.

The first fastening portion may be formed on the stepped surface, and the second fastening portion may be formed on a contact portion of the supporting portion that contacts the stepped surface.

The first fastening portion may be formed on the outer surface of the lower portion or the upper portion, and formed on a contact portion of the supporting portion that contacts the rotating portion on which the first fastening portion is formed.

One of the first fastening portion and the second fastening portion may include a protruding member protruding from a contact portion between the rotating portion and the supporting portion. The other of the first fastening portion and the second fastening portion may include a receiving groove recessed in the contact portion.

The protruding member may be formed on an outer side surface of the lower portion or the upper portion and on the stepped surface. The receiving groove may be formed on each contact portion of the supporting portion that contacts the outer surface of the rotating portion on which the protruding member is formed.

An adhesive may be applied onto the contact portion between the rotating portion and the supporting portion, and be received by the receiving groove.

Based on a state observed from above, the protruding member and the receiving groove may be in an annular form.

The supporting portion may have a seating groove formed on an outer surface of the supporting portion, the seating portion on which an edge of a substrate is to be seated.

The rotating potion may include a first material, and the supporting portion may include a second material having a level of hardness less than that of the first material.

According to another example embodiment, there is provided a substrate support device including a plurality of substrate holders. The plurality of substrate holders may support a plurality of portions of an edge of a substrate and rotate at a same speed to rotate the substrate.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1 is a perspective view of an example of a substrate support device according to an example embodiment;

FIG. 2 is a top view of an example of a substrate support device according to an example embodiment;

FIG. 3 is a perspective view of an example of a substrate holder according to an example embodiment;

FIG. 4 is a cross-sectional view of an example of a substrate holder according to an example embodiment;

FIG. 5 is a cross-sectional view of an example of a substrate holder according to an example embodiment;

FIG. 6 is a cross-sectional view of an example of a substrate holder according to an example embodiment;

FIG. 7 is a cross-sectional view of an example of a substrate holder according to an example embodiment; and

FIG. 8 is a cross-sectional view of another example of a substrate holder according to an example embodiment.

### DETAILED DESCRIPTION

Hereinafter, some example embodiments will be described in detail with reference to the accompanying drawings. However, various alterations and modifications may be made to the example embodiments. Here, the example embodiments are not construed as limited to the disclosure and should be understood to include all changes, equivalents, and replacements within the idea and the technical scope of the disclosure.

The terminology used herein is for the purpose of describing particular examples only and is not to be limiting of the examples. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof. In addition, terms such as first, second, A, B, (a), (b), and the like may be used herein to describe components. Each of these terminologies is not used to define an essence, order, or sequence of a corresponding component but used merely to distinguish the corresponding component from other component(s). It should be noted that if it is described in the specification that one component is “connected,” “coupled,” or “joined” to another component, a third component may be “connected,” “coupled,” and “joined” between the first and second components, although the first component may be directly connected, coupled or joined to the second component.

The same name may be used to describe an element included in the example embodiments described above and an element having a common function. Unless otherwise mentioned, the descriptions on the example embodiments may be applicable to the following example embodiments, and thus duplicated descriptions will be omitted for conciseness.

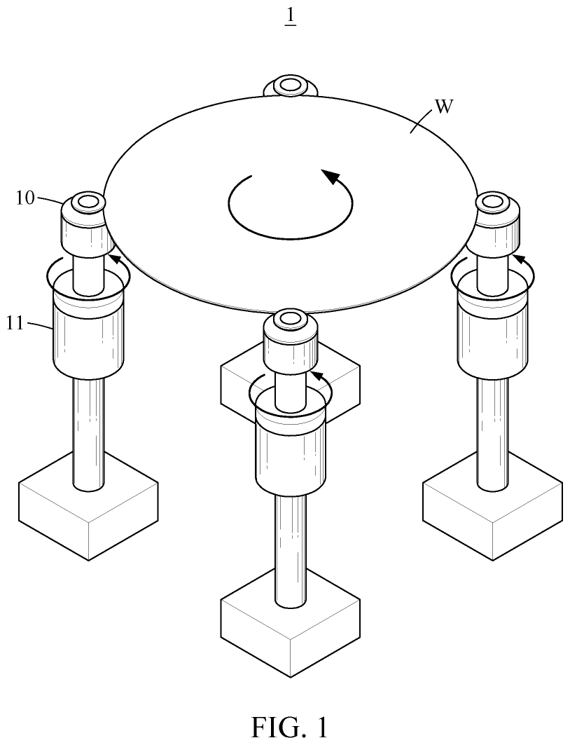

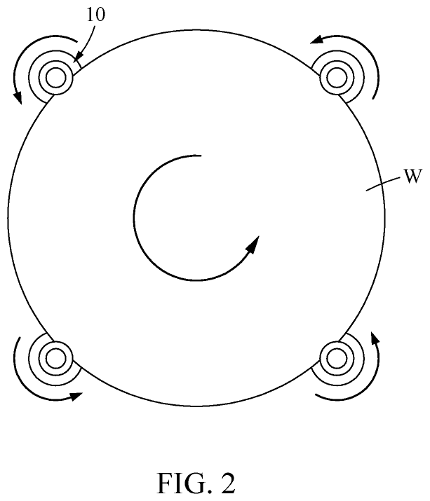

FIG. 1 is a perspective view of a substrate support device according to an example embodiment, and FIG. 2 is a top view of a substrate support device according to an example embodiment.

Referring to FIGS. 1 and 2, a substrate support device 1 may support a substrate W for a cleaning process for the substrate W. The substrate support device 1 may rotate the substrate W while maintaining a position of the substrate W. To a surface of the substrate W supported by the substrate support device 1, a cleaning fluid, a liquid chemical, and the like may be fed to remove foreign residues.

The substrate W to be supported by the substrate support device 1 may be a silicon wafer that is used as a semiconductor substrate. However, types of substrate are not limited to the foregoing, and the substrate W may be a glass substrate for a flat panel display (FPD) such as a liquid crystal display (LCD) and a plasma display panel (PFD). The substrate W may be of a circular form, and a size thereof may vary from a small size to a large size based on an application purpose.

The substrate support device 1 includes a plurality of substrate holders 10 that support a plurality of portions of an edge of the substrate W. Although the substrate support device 1 is illustrated as including four substrate holders 10, the substrate support device 1 may include three or more substrate holders 10.

The substrate holders 10 may rotate on an axis perpendicular to a surface of the substrate W. The axis on which the substrate holders 10 rotate will be referred to hereinafter as a rotation axis. The substrate holders 10 may rotate at a same speed. When the substrate holders 10 rotate while being in contact with the edge of the substrate W, the substrate W may rotate on a central axis by a frictional force generated between the substrate W and the substrate holders 10. Thus, the cleaning fluid or the liquid chemical fed to the substrate W may be evenly distributed to an outer side from a center of the substrate W by the rotation.

Hereinafter, a substrate holder 10 will be described according to an example embodiment. In the following description of the substrate holder 10, a repeated description will be omitted for increased clarity.

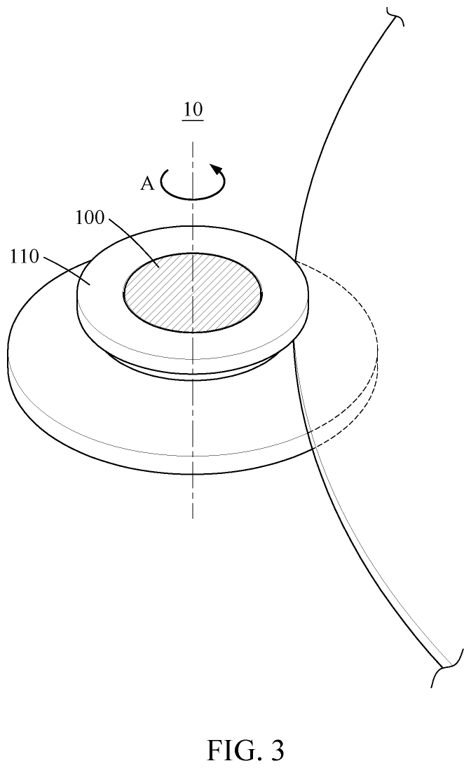

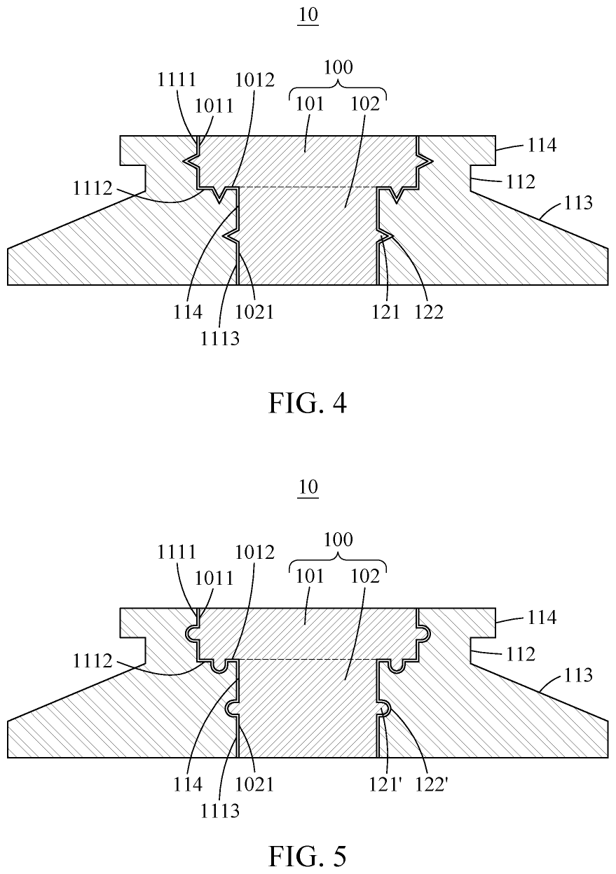

FIG. 3 is a perspective view of the substrate holder 10 according to an example embodiment, and FIG. 4 is a cross-sectional view of an example of the substrate holder 10 according to an example embodiment.

Referring to FIGS. 3 and 4, the substrate holder 10 may rotate while supporting an edge of a substrate W. The substrate holder 10 includes a rotating portion 100, a supporting portion 110, a first fastening portion 121, and a second fastening portion 122.

The rotating portion 100 may rotate on a rotation axis. The rotating portion 100 is connected to a shaft that rotates on an axis perpendicular to the ground, and rotates by the rotation of the shaft that is rotating. A motor 11 is connected to the shaft. The rotating portion 100 is integrally connected to the shaft through a fastening screw that passes through an upper portion of the rotating portion 100.

The rotating portion 100 may have a circular shape when observed from above. The rotating portion 100 is divided into a lower portion 102 and an upper portion 101 in a height direction. The lower portion 102 and the upper portion 101 may be stepped outwardly. Thus, there is a stepped surface 1012 formed between the upper portion 101 and the lower portion 102.

The rotating portion 100 includes an outer surface formed by each of the lower portion 102 and the upper portion 101, based on a cross section parallel to the rotation axis as illustrated in FIG. 4. For example, based on the cross section, an outer surface 1021 of the lower portion 102 and an outer surface 1011 of the upper portion 101 are parallel to the rotation axis. When the upper portion 101 protrudes farther outwards than the lower portion 102 as illustrated, the stepped surface 1012 may be formed under the upper portion 101. In such a case, the stepped surface 1012 may be disposed on a plane vertical to the rotation axis.

The rotating portion 100 may be formed with a first material. The first material may have a level of hardness that is higher than that of a second material to be described hereinafter. The first material may be connected while being fixed when the rotating portion 100 is connected to the shaft, and have a level of hardness that maintains a consistent level of connection even when the rotating portion 100 rotates for a long period of time. The first material may include at least one of polyether ether ketone (PEEK), polyacetal or polyoxymethylene (POM), polyimide (PA), polyvinyl chloride (PVC), polypropylene (PP), acrylonitrile butadiene styrene (ABS) resin, polyvinylidene fluoride (PVDF), or unsaturated polyester (UPE), for example.

The supporting portion 110 is connected to the outer surface of the rotating portion 100. The supporting portion 110 is connected to the rotating portion 100 in a way that the rotating portion 100 is inserted into the supporting portion 110. For example, the supporting portion 110 may include an inserting portion formed in a shape corresponding to that of the outer surface of the rotating portion 100. Thus, the supporting portion 110 may surround the outer surface in a circumferential direction of the rotating portion 100 with the rotating portion 100 being inserted in the inserting portion of the supporting portion 110.

The inserting portion may be formed in a shape corresponding to that of the outer surface of the rotating portion 100. Based on the cross section illustrated in FIG. 4, the inserting portion includes a lower insertion surface 1113 that contacts the outer surface of the lower portion 102, an upper insertion surface 1111 that contacts the outer surface of the upper portion 101, and a stepped insertion surface 1112 that contacts the stepped surface 1012 of the rotating portion 100.

That is, when the upper portion 101 and the lower portion 102 of the rotating portion 100 are different in size, the shape of the inserting portion of the supporting portion 110 may also be formed corresponding to a shape of the outer surface of the rotating portion 100. In such a structure, a contact area for connecting the rotating portion 100 and the supporting portion 110 may increase, and thus the supporting portion 110 may be more tightly connected to the rotating portion 100.

The supporting portion 110 may support the edge of the substrate W through the outer surface. Based on the cross section illustrated in FIG. 4, the outer surface of the supporting portion 110 includes a seating groove 112 that is recessed inwardly such that the edge of the substrate W becomes closer. Based on the seating groove 112, the supporting portion 110 includes an upper outer surface 114 that is stepped outwardly from an upper portion of the seating groove 112, and a lower tilted outer surface 113 that is tilted downwards from a lower portion of the seating groove 112 and has an increasing diameter.

The lower tilted outer surface 113 may function as a guide that assists the substrate W in moving to the seating groove 112 along the lower tilted outer surface 113 when the substrate W is being inserted into the seating groove 112. The substrate W may be inserted into the seating groove 112 along such a tilt of the lower tilted outer surface 113, and it is thus possible to prevent an excessive force from being applied to the edge of the substrate W.

The supporting portion 110 may perform a function of rotating the substrate W by supporting the edge of the substrate W. The supporting portion 110 may include the second material having a lower level of hardness than the first material. The second material may be a flexible material having a frictional force that sufficiently supports the substrate W. The second material may include one of natural rubber (NB), nitrile butadiene rubber (NBR) such as acrylonitrile-butadiene rubber, fluoroelastomer (FKM), polybutadiene rubber (BR), and urethane, for example. When the second material has the hardness lower than that of the first material, it is possible to absorb an impact generated when the substrate W is supported, and thus prevent the substrate W from being damaged. In addition, it is possible to prevent the substrate W from being slipped during a rotation of the substrate W due to a frictional force.

The rotating portion 100 is formed with the first material having the higher level of hardness, and it is thus possible to stably maintain a connection between the supporting portion 110 and the rotating portion 100 even when the supporting portion 110 is deformed while supporting the substrate W.

The first fastening portion 121 and the second fastening portion 122 may tightly connect the rotating portion 100 and the supporting portion 110 such that the rotating portion 100 and the supporting portion 110 are stably fastened together without being disconnected. The first fastening portion 121 and the second fastening portion 122 are formed in the rotating portion 100 and the supporting portion 110, respectively, and fastened to each other. The first fastening portion 121 is formed on the outer surface of the rotating portion 100, and the second fastening portion 122 is formed on the contact surface of the supporting portion 110 that contacts the outer surface of the rotating portion 100, for example, a surface of the inserting portion.

Each of the first fastening portion 121 and the second fastening portion 122 may be provided as a plurality of fastening potions. For example, as illustrated in FIG. 4, the first fastening portion 121 is formed on at least one of the outer surface 1011 of the upper portion 101 of the rotating potion 100, the outer surface 1021 of the lower portion 102 of the rotating portion 100, or the stepped surface 1012. In this example, the second fastening portion 122 is formed on one of the upper insertion surface 1111, the lower insertion portion 1113, and the stepped insertion surface 1112, and is fastened to the first fastening portion 121 formed at a corresponding position.

One of the first fastening portion 121 and the second fastening portion 122 includes a protruding member that protrudes from a contact portion between the rotating portion 100 and the supporting portion 110. In such a case, the other one of the first fastening portion 121 and the second fastening portion 122 includes a receiving groove that is recessed in the contact portion between the rotating portion 100 and the supporting portion 100 to receive the protruding member.

For example, as illustrated in FIG. 4, the first fastening portion 121 may include a protruding member that protrudes on a surface of the rotating portion 100, and the second fastening portion 122 may include a receiving groove that is recessed in a receiving portion of the supporting portion 110. For another example, the second fastening portion 122 may include a protruding member in the receiving portion, and the first fastening portion 121 may include an receiving groove that is recessed on the surface of the rotating portion 100. Hereinafter, the first fastening portion 121 and the second fastening portion 122 will be described as including the protruding member and the receiving groove, respectively, for the convenience of description.

The protruding member is formed along a circumference in the circumferential direction of the rotating portion 100. That is, based on a state observed from above, the protruding member is formed in an annular shape. However, the protruding member may also protrude partially from the surface of the rotating portion 100. For example, when the protruding member is provided as a plurality of protruding members each protruding partially from the surface of the rotating portion 100, the supporting portion 110 may also include a plurality of receiving grooves corresponding to the plurality of the protruding members. In this example, when each of the protruding members is inserted in a corresponding one of the receiving grooves to connect the rotating portion 100 and the supporting portion 110, it is possible to prevent the supporting portion 110 from rotating relative to the rotating portion 100 through the connection between the protruding members and the receiving grooves.

The protruding member and the receiving groove may be formed in various shapes. For example, as illustrated in FIG. 4, the protruding member may be provided in a shape having a triangular cross section narrowed in a form of a tip, and the receiving groove may be provided in a shape having a triangular cross section recessed.

The rotating portion 100 and the supporting portion 110 may be connected through an adhesive that is applied onto the contact portion therebetween. By an adhesive force of the adhesive, it is possible to improve the connection between the rotating portion 100 and the supporting portion 110. In such a case, the adhesive may be received by the receiving groove formed in the contact portion between the rotating portion 100 and the supporting portion 110. Thus, it is possible to improve the connection between the rotating portion 100 and the supporting portion 110 through the adhesive and at the same time, prevent the adhesive from being leaked outside the contact portion.

Thus, the first fastening portion 121 and the second fastening portion 122 may prevent the supporting portion 110 from being separated from the rotating portion 100 by an impact generated when the rotating portion 100 rotates while the rotating portion 100 and the supporting portion 110 are connected to each other.

For example, when the first fastening portion 121 is formed on the outer surface 1011 of the upper portion 101 or the outer surface 1021 of the lower portion 102, and the second fastening portion 122 is formed on the upper insertion surface 1111 or the lower insertion surface 1113, the first fastening portion 121 and the second fastening portion 122 may be fastened together, which may correspond to a vertical-direction force that acts between the rotating portion 100 and the supporting portion 110. Thus, it is possible to effectively prevent the supporting portion 110 from being detached from the rotating portion 100.

In addition, when the first fastening portion 121 is formed on the stepped surface 1012 and the second fastening portion 122 is formed on the stepped insertion surface 1112, the first fastening portion 121 and the second fastening portion 122 may provide a locking force in a horizontal direction, and at the same time, increase a contact area between the rotating portion 100 and the supporting portion 110 and improve the adhesive force by the adhesive.

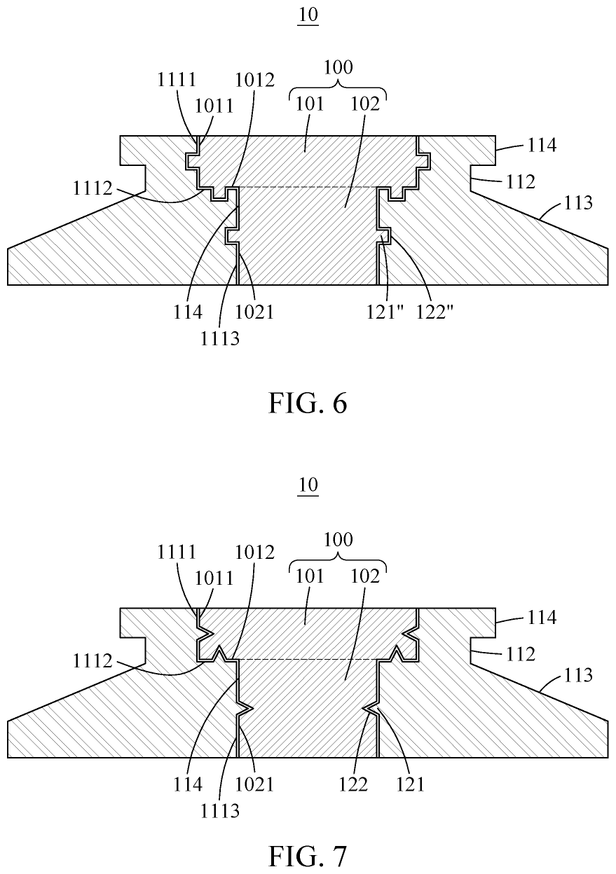

FIG. 5 is a cross-sectional view of an example of the substrate holder 10 according to an example embodiment, and FIG. 6 is a cross-sectional view of an example of the substrate holder 10 according to an example embodiment.

Referring to FIGS. 5 and 6, the protruding member and the receiving groove may be provided in various forms. For example, as illustrated in FIG. 5, a protruding member 121′ may have a cross-sectional shape that is rounded hemispherically, and a receiving groove 122′ may have a cross-sectional shape that is recessed hemispherically.

For another example, as illustrated in FIG. 6, a protruding member 121″ may protrude in a quadrangular cross-sectional shape, and a receiving groove 122″ may be recessed in a corresponding quadrangular cross-sectional shape.

FIG. 7 is a cross-sectional view of an example of the substrate holder 10 according to an example embodiment.

Referring to FIG. 7, the substrate holder 10 includes the rotating portion 100, the supporting portion 110, the first fastening portion 121, and the second fastening portion 122.

The first fastening portion 121 includes the receiving groove that is recessed on the surface of the rotating portion 100. The second fastening portion 122 includes the protruding member that protrudes from the surface of the inserting portion of the supporting portion 110 and is to be connected to the receiving groove through insertion.

In such a case, the first fastening portion 121 includes a receiving groove formed on each of the upper portion 101, the lower portion 102, and the stepped surface 1012 of the rotating portion 100. The second fastening portion 122 includes a protruding member formed on each of the upper insertion surface 1111, the lower insertion surface 1113, and the stepped insertion surface 1112 of the supporting portion 110. Each receiving groove and protruding member may be connected to each other, and thus maintain a tight connection between the rotating portion 100 and the supporting portion 110.

Although all of a plurality of first fastening portions 121 are illustrated as including protruding members and all of a plurality of second fastening portions 122 are illustrated as including receiving grooves, the first fastening portions 121 may include a protruding member and a receiving groove in a mixed way and the second fastening portions 122 may also include a protruding member and a receiving groove in a mixed way.

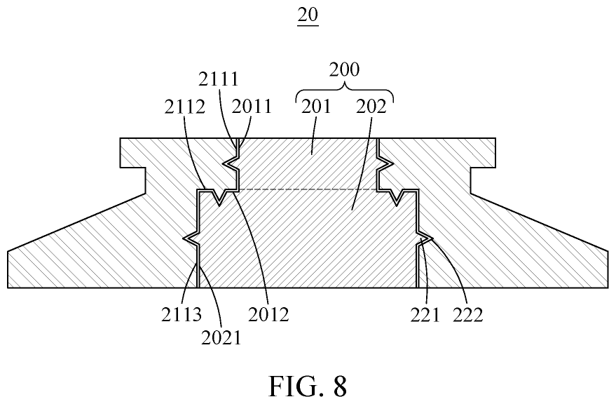

FIG. 8 is a cross-sectional view of another example of a substrate holder according to an example embodiment.

Referring to FIG. 8, a substrate holder 20 includes a rotating portion 200, a supporting portion 210, a first fastening portion 221, and a second fastening portion 222.

The rotating portion 200 includes an upper portion 201 and a lower potion 202. Based on a cross section, an outer surface 2021 of the lower portion 202 protrudes farther outwardly than an outer surface 2011 of the upper portion 201. In such a case, a stepped surface 2022 between the upper portion 201 and the lower portion 202 is formed on an upper surface of the lower portion 202.

The supporting portion 210 includes an inserting portion corresponding to a shape of a surface of the rotating portion 200, and a surface of the inserting portion includes an upper receiving groove 2111, a lower receiving groove 2113, and a stepped receiving groove 2112 based on each contact portion of the rotating portion 200.

When the surface of each portion of the rotating portion 200 is formed to be stepped as described above, a contact area between the rotating portion 200 and the supporting portion 210 may increase when connecting the rotating portion 200 and the supporting portion 210, and thus a portion onto which an adhesive is to be applied may also increase.

According to example embodiments described herein, a substrate holder and a substrate support device including the substrate holder may effectively prevent a supporting portion and a rotating portion from being separated during a rotation by increasing a contact area between the supporting portion and the rotating portion.

According to example embodiments described herein, a substrate holder and a substrate support device including the substrate holder may achieve a locking function both in a horizontal direction and in a vertical direction by a first fastening portion and a second fastening portion being fastened together.

The advantageous effects of the substrate holder and the substrate support device including the substrate holder may not be limited to what is described in the foregoing, and other effects that are not described above may also be understood by those skilled in the art from the description provided herein.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A substrate holder comprising:
a rotating portion configured to rotate on a rotation axis;
a supporting portion connected to the rotating portion to surround an outer surface of the rotating portion in a circumferential direction of the rotating portion; and
a first fastening portion formed on the outer surface of the rotating portion, and a second fastening portion formed on a contact surface of the supporting portion that contacts the rotating portion and configured to be fastened to the first fastening portion.

2. The substrate holder of claim 1, wherein the rotating portion comprises a lower portion and an upper portion that are stepped with each other outwardly,
wherein the lower portion and the upper portion have a stepped surface that is formed therebetween.

3. The substrate holder of claim 2, wherein, based on a cross section parallel to the rotation axis, an outer surface of the lower portion and an outer surface of the upper portion are parallel to the rotation axis, and the stepped surface is perpendicular to the rotation axis.

4. The substrate holder of claim 2, wherein the first fastening portion is formed on the stepped surface, and the second fastening portion is formed on a contact portion of the supporting portion that contacts the stepped surface.

5. The substrate holder of claim 2, wherein the first fastening portion is formed on an outer surface of the lower portion or the upper portion, and formed on a contact portion of the supporting portion that contacts the rotating portion on which the first fastening portion is formed.

6. The substrate holder of claim 2, wherein one of the first fastening portion and the second fastening portion comprises a protruding member protruding from a contact portion between the rotating portion and the supporting portion, and
the other of the first fastening portion and the second fastening portion comprises a receiving groove recessed in the contact portion.

7. The substrate holder of claim 6, wherein the protruding member is formed on an outer side surface of the lower portion or the upper portion and on the stepped surface, and
the receiving groove is formed on each contact portion of the supporting portion that contacts the outer surface of the rotating portion on which the protruding member is formed.

8. The substrate holder of claim 6, wherein an adhesive is applied onto the contact portion between the rotating portion and the supporting portion,
wherein the adhesive is received by the receiving groove.

9. The substrate holder of claim 6, wherein, based on a state observed from above, the protruding member and the receiving groove are in an annular form.

10. The substrate holder of claim 1, wherein the supporting portion has a seating groove formed on an outer surface thereof, the seating portion on which an edge of a substrate is to be seated.

11. The substrate holder of claim 1, wherein the rotating potion comprises a first material, and
the supporting portion comprises a second material having a level of hardness less than that of the first material.
